(19) United States
(12) Patent Application Publication
(10) Pub. No.: US 2009/0323895 A1
(43) Pub. Date: Dec. 31, 2009

(54) Method and Apparatus for Treating Workpieces

(75) Inventors: Alois Friedberger, Glonn (DE); Thorsten Loewer, Brachttal (DE); Soeren Fricke, Hoehenkirchen-Siegertsbrunn (DE); Ulrich Schmid, Saarbruecken (DE)

Correspondence Address: CROWELL & MORING LLP;INTELLECTUAL PROPERTY GROUP, P.O. BOX 14300, WASHINGTON, DC, 20044-4300, US

(73) Assignees: Eads Deutschland GmbH, Ottobrunn (DE); pro beam AG-Co. KgaA, Planegg (DE)

(21) Appl. No.: 12/307,453

(22) PCT Filed: May 30, 2007
(86) PCT No.: PCT/EP2007/004781

§ 371 Date: Jul. 2, 2009

(30) Foreign Application Priority Data
Jul. 4, 2006 (DE) 102006030874.3

(51) Int. Cl. G01B 15/02; H01J 37/305; H01J 37/304

(52) U.S. Cl. 378/54; 250/492.3

(57) ABSTRACT

An electron beam is used to generate x-ray radiation in a workpiece, which radiation emerges on the workpiece back at sufficiently thin points of the workpiece and is detected by means of an x-ray radiation detector. Based on the x-ray radiation intensity and the momentary beaming-in position of the electron beam, the surface structure on both sides as well as the local material thickness can be determined. Based on such values, workpieces and/or workpiece treating systems can be adjusted, and vertical material removal in a material-removing workpiece treating system can be controlled.

### BACKGROUND AND SUMMARY OF THE INVENTION

This application is a national stage of International Application No. PCT/EP/2007/004781, filed Jan. 10, 2008, which claims priority under 35 U.S.C. §119 to German Patent Application No. 10 2006 030 874.3, filed Aug. 3, 2007, the entire disclosure of which is herein expressly incorporated by reference.

The invention relates to a method and apparatus for treating a workpiece using electron radiation. Within the scope of the present invention, treating a workpiece includes material-altering treatment (particularly the removal of material), as well as material-neutral treatment (particularly the measurement of workpieces).

Various basic problems must be overcome when treating workpieces. A first problem is precisely positioning the workpiece before it is to be treated, for example, in a material-altering manner. Such positioning may, for example, depend on the position of hard surface structures. Particularly in the case of workpieces consisting of non-transparent materials, exact positioning is difficult when it depends on the position of surface structures situated on the back of the workpiece. The workpiece therefore has to be measured and/or the treatment system has to be correspondingly adjusted at high expenditures.

A second problem is determining the remaining thickness of the material layer when material is removed. This problem occurs, for example, during material-removing workpiece treatment by means of an electron beam, but also, for example, during the wet-chemical etching of silicon wafers.

A further problem consists of terminating the material removal precisely when a layer boundary has been reached during the material-removing treatment of a multi-layer workpiece.

One object of the present invention is to provide a common operating principle, by which all above-mentioned problems can be solved in a simple and elegant manner.

This and other objects and advantages are achieved by the method and apparatus according to the invention, in which the workpiece is irradiated on a first workpiece side, by electron radiation which is selected such that it generates x-ray radiation in the material of the workpiece. The x-ray radiation emerging from the workpiece on a second workpiece side situated opposite the first workpiece side will then be detected.

A system according to the invention for treating workpieces therefore includes, in addition to a workpiece receiving device, a corresponding electron radiation source on a first side of the workpiece receiving device and a corresponding x-ray radiation detector on a second side of the workpiece receiving device opposite the first side, which x-ray radiation detector is situated opposite the electron radiation source.

The invention utilizes the fact that electron beams generate x-rays in the material, which can be detected by a simple detector. Although the material itself absorbs the x-rays again, starting at a certain material thickness, the x-rays are no longer completely absorbed by the material. By detecting the x-ray radiation emerging on the back of the workpiece, a conclusion can be drawn concerning the thickness of the material layer on the concerned side.

On the one hand, the same principle can also be used for measuring the workpiece surface and determining concrete surface structures. In this case, the electron radiation is expediently selected to be so low that it does not alter the material. Preferably, a bundled electron beam is used to scan the first workpiece, for example, along one or more lines. By means of changing x-ray radiation intensity values, at points of the workpiece which are sufficiently thin for the x-ray radiation generated in the workpiece by the electron beam to emerge at the back of the workpiece, a conclusion concerning surface structures can be drawn. However, without additional information, no reliable conclusion can be drawn as to whether those surface structures are situated on the front of the workpiece, the back of the workpiece or both sides. At any rate, by means of the amount of the detected x-ray radiation intensity, a measurement can be derived for the layer thickness and a layer thickness profile which can be exactly quantified by a comparison with material-dependent reference values.

However, if surface structures on the workpiece front and on the workpiece back are known but not their vertical distance from one another and/or their lateral position with respect to one another, a conclusion can be drawn with respect to their relative vertical and lateral position, based on the determined thickness profile. In particular, this makes it possible to position a workpiece laterally in a precise manner before it is further processed in any fashion.

During a (subsequent) material-removing workpiece treatment, the measuring principle according to the invention can be used, for example, to determine a residual layer thickness. As soon as the removal of material has progressed so far that the x-ray radiation generated in the material by the electron radiation is not completely absorbed on its path through the remaining material layer thickness, but emerges at the back of the workpiece, the x-ray radiation intensity detected on the back of the workpiece can be used as a measurement for the remaining layer thickness, and can be analyzed. As soon as the detected x-ray radiation reaches or exceeds a given threshold value, which defines a certain material layer thickness for the concerned material, the material removal operation can be terminated. This principle is particularly suitable for methods by which the material is removed by the electron beam itself. However, it is equally suitable for other methods by which the removal of material takes place in a different fashion.

It is also possible to let the respective actually detected x-ray radiation, (hence, the actual thickness value) influence a control loop, to control the removal of material as a control variable. For example, the power of an electron beam causing the removal of material may be appropriately reduced, the closer one comes to the desired residual thickness of the layer of material. In this case, the detected x-ray radiation is always a function of the beamed-in electron beam intensity per surface, of the material layer thickness and of the material itself.

A further interesting possibility of controlling a material-removing treatment process using the principle according to the invention consists of terminating the material removal in the vertical direction precisely when a layer boundary has been reached in a multi-layer material. In this case, the physical characteristic is utilized that the x-ray spectrum of the x-ray radiation generated by the electron radiation differs for different materials. When a layer boundary is reached, the characteristic of the detected x-ray radiation therefore changes abruptly.

The invention can therefore be used in multiple respects for the treatment of workpieces, particularly during the workpiece adjusting for the lateral position determination or during the removal of material for the vertical position determination or for both. The invention is, for example, suitable for use in the manufacture of micro components for high-temperature pressure sensor systems, particularly for the control of the membrane thickness when etching silicon and determining the residual membrane thickness.

Other objects, advantages and novel features of the present invention will become apparent from the following detailed description of the invention when considered in conjunction with the accompanying drawings.

### BRIEF DESCRIPTION OF THE DRAWINGS

FIG. 1 is a schematic view of an embodiment of a system according to the invention for the treatment of workpieces;

FIG. 2 is a schematic view of the operation of scanning a workpiece by means of an electron beam; and

FIG. 3 is a schematic view of the operation of removing material by means of an electron beam.

### DETAILED DESCRIPTION OF THE DRAWINGS

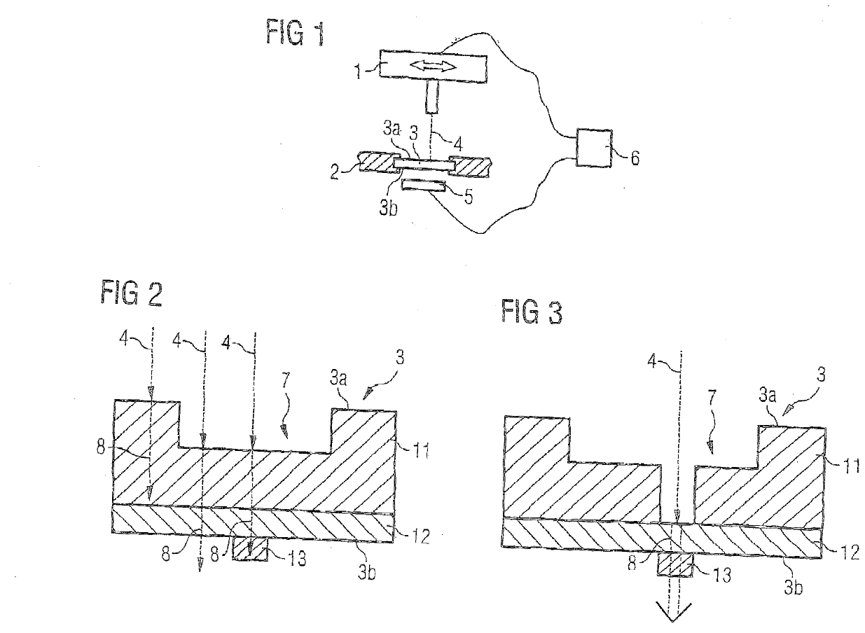

FIG. 1 is a schematic view of a system for treating workpieces according to an embodiment of the invention. The system comprises an electron beaming device 1, which can be displaced parallel to a workpiece 3 in a workpiece receiving device 2, in order to move the electron beam emerging from the electron beaming device 1 over the surface of a first side 3a of the workpiece 3. To the extent that it exits from the back 3b of the workpiece 3, the x-ray radiation generated by the electron beam 4 in the material of the workpiece 3, is detected by means of an x-ray radiation detector 5 which, relative to the workpiece receiving device 2, is arranged opposite the electron beaming device 1.

The electron beaming device 1 and the x-ray radiation detector 5 are connected to an analyzing device 6 which takes into account the actual position of the electron beaming device 1 and the x-ray radiation detected by the x-ray radiation detector 5, and determines the thickness of the workpiece 3 at the point of the workpiece irradiated by the electron beam 4 at the particular point in time. Because the electron radiation impinges on a defined point of the workpiece 3 as a bundled electron beam 4, the x-ray radiation detector 5 itself does not have to operate in a locally resolved manner. For the local resolution, the electron beaming direction of the electron beam 4 or the actual position of the electron beaming device 1 can be used.

The system according to FIG. 1 can detect the surface contour of the workpiece 3 by scanning it with a suitable, relatively low electron radiation intensity. This is successful to the extent that the radiation intensity is sufficiently high and the material thickness is sufficiently narrow for the x-ray radiation generated by means of the electron beam 4 in the workpiece to emerge on the back 3b of the workpiece 3.

On the other hand, the system according to FIG. 1, can also determine the residual thickness of the workpiece 3 during the material-removing workpiece treatment, particularly when the electron beam itself causes the removal of the material. Based on the determined residual thickness, the removal process can be controlled and/or can be stopped at a given residual thickness.

FIG. 2 is a schematic view of the operation of scanning the surface of a multi-layer workpiece 3, which consists of a total of three layers 11, 12, 13. The top side 3a of the workpiece 3, on which the electron radiation 4 impinges, has an indentation 7. The bottom layer 13 is present only locally in the area of the recess 7.

When scanning the surface 3a by means of the electron beam 4 for determining the relative lateral position of the lower local layer 13 with respect to the upper recess 7, the electron beam 4 sweeps from the left to the right first over a relatively thick area of the workpiece 3 in which the x-ray radiation 8 generated in the workpiece 3 by the electron radiation 4 is completely absorbed on its path to the workpiece back 3b. As soon as the electron beam 4 reaches the recess 7, the layer thickness of the workpiece 3 becomes sufficiently narrow for the generated x-ray radiation 8 to emerge on the back of the workpiece 3b, so that it can be detected by the x-ray radiation detector 5 (not shown in FIG. 2).

In the further course, the electron beam 4 sweeps over the local coating 13. In this section, no x-ray radiation exits on the back 3b of the workpiece 3 since it is completely absorbed as a result of the increased layer thickness of the material. Even if it were not absorbed completely, the x-ray radiation intensity emerging in this section would at least decrease, so that the relative position of the local layer 13 with respect to the opposite indentation 7 would nevertheless be clearly detectable. On the basis of the data thus determined measuring, the workpiece and/or the workpiece treating system can be precisely adjusted for the further treating of the workpiece 3.

FIG. 3 shows the same workpiece 3 after a material-removing treatment by means of a correspondingly stronger electron beam 4. Since previously the exact relative position of the local layer 13 on the workpiece back 3b had been determined relative to the workpiece front 3a, it becomes possible to vertically remove the layer 11 in exactly the section situated above the local layer 13.

In this case, the x-ray radiation detector 5 (not shown in FIG. 3) will at first detect a continuous increase of the x-ray radiation intensity. As soon as the layer 11 has been removed to the boundary to layer 12, the x-ray radiation spectrum of the x-ray radiation 8 generated by the electron beam 4 in the workpiece 3 will change because of the different behavior of the material of layers 11 and 12. This is correspondingly recorded by the analyzing device 6 and the further removal of material is stopped at the concrete point. The electron beam is moved back and forth until, at any point of the section situated over the local coating 13, the material of layer 11 is removed to layer 12.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1.-22. (canceled)

23. A method for treating a workpiece, said method comprising:
irradiating a first side of the workpiece with electron radiation which is selected such that it generates x-ray radiation in the material of the workpiece; and
detecting x-ray radiation emerging from a second side of the workpiece situated opposite the first workpiece side.

24. The method according to claim 23, wherein said step of irradiating the workpiece is performed using a bundled electron beam.

25. The method according to claim 24, wherein the first side of the workpiece is scanned by means of the electron beam.

26. The method according to claim 25, further comprising:
drawing conclusions with respect to surface structures on one of the first and second sides of the workpiece by analyzing the x-ray radiation detected on the second workpiece side.

27. The method according to claim 25, wherein the step of determining the position of surface structures on the first workpiece side relative to surface structures on the second workpiece side by analyzing the x-ray radiation detected on the second workpiece side.

28. The method according one of claim 23, wherein material of the workpiece is removed on the first workpiece side.

29. The method according to claim 28, wherein the removal of the material takes place by the irradiation of the workpiece by means of the electron beam.

30. The method according to claim 28, wherein removal of the material is terminated at an actual electron beam impinging site when x-ray radiation detected on the second workpiece side reaches or exceeds a given threshold value.

31. The method according to claim 28, wherein the removal of the material is terminated at an actual electron beam impinging site when a characteristic of the detected x-ray radiation changes.

32. The method according to claim 28, wherein detected x-ray radiation, as a control value, influences a control loop controlling the removal of the material.

33. The method according to claim 24, wherein electron beaming direction of the electron beam at a detection point in time is used for local resolution of the detected x-ray radiation.

34. Apparatus for treating workpieces, said apparatus comprising:
a workpiece receiving device;
an electron radiation source disposed on a first side of the workpiece receiving device, for irradiating a workpiece in the workpiece receiving device by means of electron radiation; and
an x-ray radiation detector which is disposed on a second side of the workpiece receiving device, opposite the first side, and is situated opposite the electron radiation source for detecting x-ray radiation emerging from a workpiece in the workpiece receiving device.

35. The apparatus according to claim 34, further comprising a device for bundling the electron radiation for generating a bundled electron beam.

36. The apparatus according to claim 34, wherein the electron beam and the workpiece receiving device can be displaced relative to one another for the purpose of scanning the surface of a workpiece in the workpiece receiving device.

37. The apparatus according to claim 36, further comprising a device for analyzing the detected x-ray radiation and drawing conclusions with respect to surface structures on one of a first side and a second side of the workpiece in the workpiece receiving device.

38. The apparatus according to claim 37, comprising a device for analyzing the detected x-ray radiation and for determining the relative position of surface structures on a first side of the workpiece relative to surface structures on a second side of the workpiece, which second side is situated opposite the first side.

39. The apparatus according to claim 34, further comprising devices for removing material from a workpiece to be received in the workpiece receiving device.

40. The apparatus according to claim 39, wherein the material removal device is the electron radiation source itself.

41. The apparatus according to claim 40, having an automatic limit stop of the material removal device when the detected x-ray radiation reaches or exceeds a given threshold value.

42. The apparatus according to claim 40, having an automatic limit stop of the material removal device when a change of a characteristic of the x-ray radiation is detected.

43. The apparatus according to claim 39, wherein a control loop controls the material removal device, which control loop is influenced by the detected x-ray radiation as a control variable.

44. The apparatus according to claim 35, wherein the x-ray radiation detector is a detector without local resolution.
